(19) United States
(12) Patent Application Publication
(10) Pub. No.: US 2007/0177363 A1
(43) Pub. Date: Aug. 2, 2007

(54) Multilayer printed circuit board having tamper detection circuitry

(75) Inventor: Jayanetti Koralalage Don Ruwan Jayanetti, Mirihana (LK)

Correspondence Address: CARTER, DELUCA, FARRELL & SCHMIDT, LLP, 445 BROAD HOLLOW ROAD, SUITE 225, MELVILLE, NY, 11747, US

(73) Assignee: Symbol Technologies, Inc.

(21) Appl. No.: 11/343,364

(22) Filed: Jan. 31, 2006

(51) Int. Cl. H05K 7/00

(52) U.S. Cl. 361/760

(57) ABSTRACT

A multilayer printed circuit board is provided. The multilayer printed circuit board includes a first and a second substrate each having a conductive signal trace; and a third substrate positioned between the first and the second substrate. The third substrate includes at least one integrated circuit mounted thereon. Tamper detection circuitry is in electrical communication with at least one of the conductive traces and is configured for providing a security response after detection of an interruption in an electrical connection provided by the at least one conductive trace.

### BACKGROUND

1. Technical Field

The present disclosure relates generally to printed circuit boards. In particular, the present disclosure relates to a multilayer printed circuit board having tamper detection circuitry.

2. Description of the Prior Art

Information or data security is provided on electronic devices, such as, computers, by a variety of methods. One simple method is to provide sensitive information on removable storage media such as a floppy disk. More sophisticated methods rely on encryption; a method of encoding information such that only a predetermined key can decode it. One increasingly popular way of breaking security is by tampering with the printed circuit board. A printed circuit board (PCB) consists generally of etched conductors attached to sheet of insulators or substrates. Typically, the PCB is adapted for receiving electronic components, such as, for example, microprocessors, random access memory, read only memory, digital signal processors, etc., and facilitating the transmission of data signals between components. For example, a payment terminal may include a PCB which includes a central processing unit having internal components for processing data, such as, for example credit card information and bank account information. These payment terminals require a high level of security for preventing unauthorized access to sensitive information contained therein. In addition, electronic payment services providers, such as banks, use electronic payment devices and systems where confidential information is received and transmitted.

The information received and transmitted by these payment terminals may be intercepted by individuals tampering with the PCB. Methods have been devised attempting to reduce and/or eliminate interception of data and tampering of the PCB's electronic components. For example, the PCB may be enclosed in a secured housing. However, such housing is typically relatively easy to tamper with. When the housing is tampered with, the PCB is accessed, making the electronic data signals readily available for unauthorized interception. Therefore, there exists a need for a PCB having tamper detection circuit for detecting tampering of the PCB and minimizing and/or eliminating unauthorized interception of electronic data signals generated and transmitted within the PCB.

### SUMMARY

The present disclosure is directed to a multilayer printed circuit board for securely facilitating the processing of sensitive and/or confidential electronic data signals within the printed circuit board. The multilayer printed circuit board includes first and second substrates positioned in adjacent relation; and a third substrate positioned between the first and the second substrate. Tamper detection circuitry is provided for providing a security response in response to detecting tampering of the multilayer printed circuit board. The security response may include total or partial destruction of the data, sounding an audio alarm, corrupting the data, and/or generating and transmitting a warning message. The multilayer printed circuit board of the present disclosure is advantageously adapted for use in a range of electronic devices and related applications.

In one embodiment, the multilayer printed circuit board includes a first and second substrate each having a conductive trace; and at least one integrated circuit mounted on a third substrate. The third substrate is sandwiched between the first and the second substrates. In addition, the at least one integrated circuit may be mounted within a ball grid array packaging. Tamper detection circuitry is provided in electrical communication with the at least one conductive traces of the first and second substrate. The tamper detection circuitry is configured to provide a security response after detection of an interruption in an electrical connection provided by the at least one conductive trace. In one embodiment, the tamper detection circuitry may include a transmitter for transmitting data signals to a remote processor indicating a security breach or tampering of the multilayer circuit board; and a receiver for receiving data signals from the remote processor.

In another embodiment, an electrical device is provided having a housing and a multilayer printed wiring board mounted within the housing. The multilayer printed wiring board includes first and second substrates each having a conductive trace, wherein the first and the second substrate are arranged in mutually parallel relationship. A third substrate positioned between the first and the second substrates. Tamper detection circuitry in electrical communication with at least one of the conductive traces and being configured to provide a security response after detection of an interruption in an electrical connection provided by the at least one conductive trace.

The present disclosure is also directed to a method for detecting tampering of a printed circuit board. The method includes mounting at least one integrated circuit onto the printed circuit board; positioning the printed circuit board between a first and second substrate; and providing a conductive trace on at least one of the first and second substrate. The method further includes providing a security response after detection of an interruption in an electrical connection provided by the conductive trace.

Other features of the presently disclosed multilayer printed circuit board will become apparent from the following detailed description, taken in conjunction with the accompanying drawings, which illustrate, by way of example, the presently disclosed multilayer printed circuit board.

### BRIEF DESCRIPTION OF THE DRAWINGS

The embodiments of the presently disclosed multilayer printed circuit board will be described herein below with reference to the figures, wherein:

FIG. 1 is a partial cross-sectional view of a multilayer printed circuit board in accordance with one embodiment of the present disclosure;

FIG. 2A is a top view of the multilayer printed circuit board of FIG. 1 illustrating one embodiment of the conductive trace within the first and second substrate;

FIG. 2B is a top view of the multilayer printed circuit board of FIG. 1 illustrating a second embodiment of the conductive trace;

FIG. 2C is a top view of the multilayer printed circuit board of FIG. 1 illustrating yet another embodiment of the conductive trace;

FIG. 2D is a top view of a multilayer printed circuit board in accordance with another embodiment of the present disclosure;

FIG. 3 is a top view of the third substrate of the multilayer printed circuit board of FIG. 1;

FIG. 4 is a flow diagram of the operation of the tamper detection circuitry of the multilayer printed circuit board of FIG. 1;

FIG. 5 illustrates an electronic payment terminal having the multilayer printed circuit board of FIG. 1 provided therein, in accordance with the present disclosure; and

FIG. 6 is a schematic block diagram of the multilayer printed circuit board within the electronic payment terminal of FIG. 5.

### DETAILED DESCRIPTION

Referring now to the drawing figures, in which like references numerals identify identical or corresponding elements, various embodiments of the presently disclosed multilayer printed circuit board will now be described in detail. The multilayer printed circuit board is advantageously configured for securely facilitating the processing of sensitive or confidential information and preventing unauthorized access to the information. A multilayer printed circuit board as defined herein encompasses any circuit board which interconnects electronic components and includes structure for detecting tampering thereof in accordance with the present disclosure. It is envisioned that the multilayer printed circuit board in accordance with the present disclosure may be employed with a range of electronic devices, such as, for example, digital appliances, electronic payment devices, point of sale terminals, and related applications.

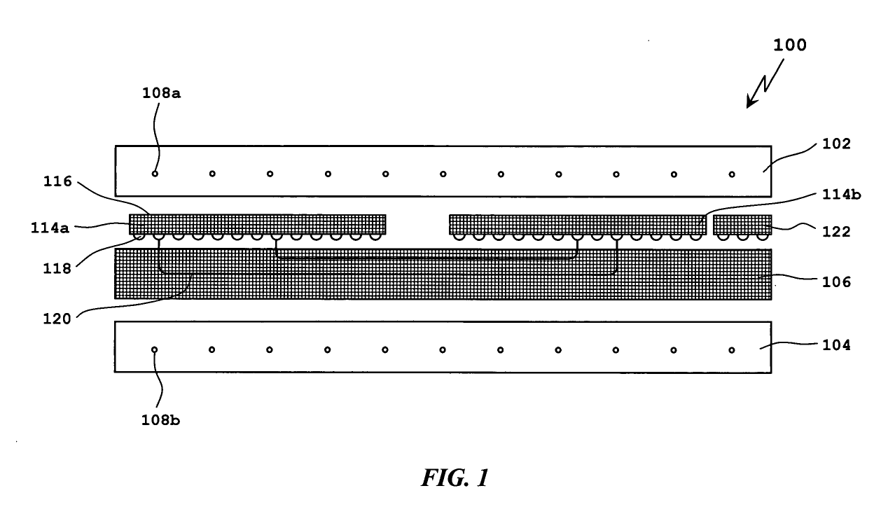

With initial reference to FIG. 1, an exemplary multilayer printed circuit board in accordance with the present disclosure is illustrated and is designated generally by reference numeral 100. Multilayer printed circuit board 100 is adapted for providing a secure medium for secure electronic communication. Multilayer printed circuit board 100 generally includes at least three layers or substrates. In particular, the multilayer printed circuit board 100 includes a first substrate 102, a second substrate 104 positioned in mutually parallel relationship with first substrate 102; and a third substrate 106 sandwiched between the first substrate 102 and the second substrate 104.

First substrate 102 and second substrate 104 are non-conductive substrates each having an etched, surface mounted conductive signal trace 108 laminated thereon. That is, the conductive signal traces 108a, 108b are mounted directly onto the surface (i.e. surface-mounted) of first and second substrates 102 and 104 for being concealed therein, thus making it difficult to visualize the exact pattern of the trace 108. Alternatively, conductive signal traces 108a, 108b may be etched in a through-hole construction as is known in the art. The conductive signal traces 108a, 108b act as a security fence module and are adapted for providing an electrical connection between two end points in a manner described in detail herein below.

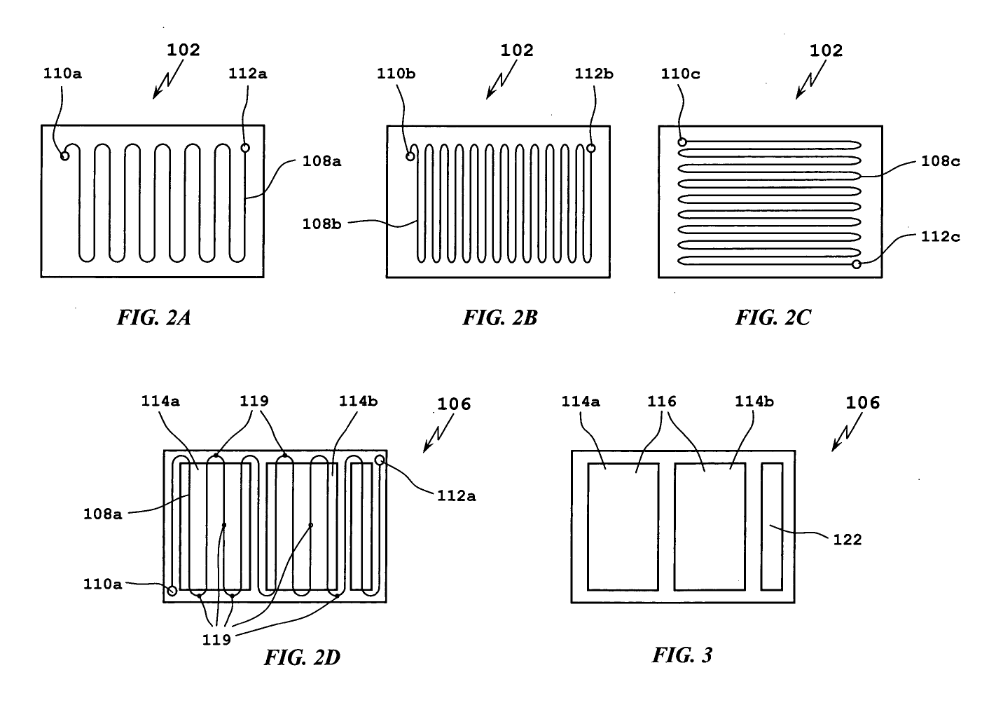

Each of the conductive signal traces 108a, 108b include at least one of a plurality of patterns and preferably encompasses the entire surface area of its respective substrate. Each conductive signal trace 108a, 108b is electrically connected to tamper detection circuitry 122. FIGS. 2A, 2B and 2C illustrate the conductive signal trace 108 having a plurality of patterns and two end points 110, 112 providing an electrical connection there between. For example, FIG. 2A illustrates the conductive signal trace 108A having a sinusoidal wave pattern. First and second end points 110A, 112B are for connecting to tamper detection circuitry 122 in a manner described herein below. FIG. 2B illustrates a conductive signal trace 108B having a high frequency sinusoidal wave pattern. The conductive signal trace 108B includes first and second end points 110B and 110B also for connecting to tamper detection circuitry 122. FIG. 2C illustrates a conductive trace 108C, which is similar to conductive signal trace 108B but rotated 90 degrees, and having first and second end points 110C and 112C. Non-sinusoidal wave patterns, such as, for example, spiral, square, triangle and saw-tooth waveforms are also envisioned as well as random patterns.

Although FIG. 1 and FIGS. 2A, 2B and 2C illustrate conductive signal traces 108a, 108b as being mounted onto the surface of first and second substrate 102 and 104 respectively, it is envisioned that third substrate 106 may be sandwiched between conductive signal traces 108a, 108b. In this particular embodiment, the conductive signal traces 108a, 108b having end points 110a, 112a are not mounted or embedded onto or within first and second substrates 102, 104. Rather, the conductive signal traces 108a, 108b are mounted onto at least one of the third substrate 106 and the integrated circuit 114a, 114b, as illustrated in FIG. 2D. FIG. 2D illustrates conductive signal trace 108a directly connected via mounting points 119 onto third substrate 106 and integrated circuits 114a, 114b. Mounting points 119 may be created using, for example, solder.

With reference to FIG. 3, the third substrate 106 will be discussed in detail. Third substrate 106 is positioned or sandwiched between first and second substrates 102, 104 and is assembled for receiving electronic components which perform a particular function or application. In one embodiment, as shown in FIGS. 1 and 3, the third substrate 106 includes at least one integrated circuit 114a, 114b. Each integrated circuit 114a, 114b includes a plurality of electronic circuits for transmitting and receiving data, such as, for example, microprocessors, Random Access Memory (RAM), Read Only Memory (ROM), Digital Signal Processors (DSP). Integrated circuits 114a, 114b may be housed within a surface-mount packaging, such as, for example, ball grid array (BGA) 116 as shown in FIG. 1.

As illustrated in FIG. 1, BGA 116 is a type of microchip connection method for conducting electrical signals via balls 118 from the integrated circuit 114 to electrical tracks 120 provided to the third substrate 106. Preferably, tracks 120 are primarily embedded within the third substrate 106 and are not exposed from the third substrate 106. Thus, all sensitive data is routed within third substrate 106. This characteristic makes the sniffing of the signals propagating along tracks 120 almost impossible without physical tampering (e.g. drilling) of the third substrate 106.

With continued reference to FIGS. 1 and 3, tamper detection circuitry 122 is positioned on the third substrate 106 and is in operative communication with conductive signal trace 108a of first substrate 102 and conductive signal trace 108b of second substrate 104 via track 120. In particular, tamper detection circuitry 122 is connected to first and second ends 110 and 112 of conductive signal trace 108. Tamper detection circuitry 122 includes circuitry for monitoring a voltage within each conductive signal trace 108. In the event of tampering with either conductive signal trace 108a, 108b, a security response is provided by the tamper detection circuitry 122.

For example, when conductive signal traces 108a, 108b are damaged and the electrical response connection is interrupted (e.g. someone drills into the first substrate 102 and/or second substrate 104 to access the third substrate 106), one or both of the conductive signal traces 108a, 108b are broken or severed and the electrical connection is interrupted. Tamper detection circuitry 122 is triggered by the interruption of the electrical connection. In one embodiment, the tamper detection circuitry 122 employs a comparator (not shown) for monitoring the current through the conductive signal traces 108a, 108b. If at least one of the conductive traces 108a, 108b is broken, or if the electrical connection between the trace 108 is interrupted, the output of the comparator would trigger or provide a security response, such as terminating the generation of data signals in integrated circuit 114. Other security responses are also envisioned within the context of the printed circuit board, such as, for example, system shut down, sounding an audio alarm, destroying data stored within the integrated circuit 114, etc.

In addition, tamper detection circuitry 122 may include a transmitter (not shown) for transmitting data signals to a remote processor and a receiver (not shown) for receiving data from the remote processor. Moreover, tamper detection circuitry 122 may also ensure that the data signals have not been corrupted during transmission from the remote processor, such as, for example, by providing some form of authentication. In addition, a protective casing (not shown) may be positioned about third substrate 106, interposed between the first substrate 102 and second substrate 104. The protective casing includes a conductive film in operable communication with tamper detection circuitry 122.

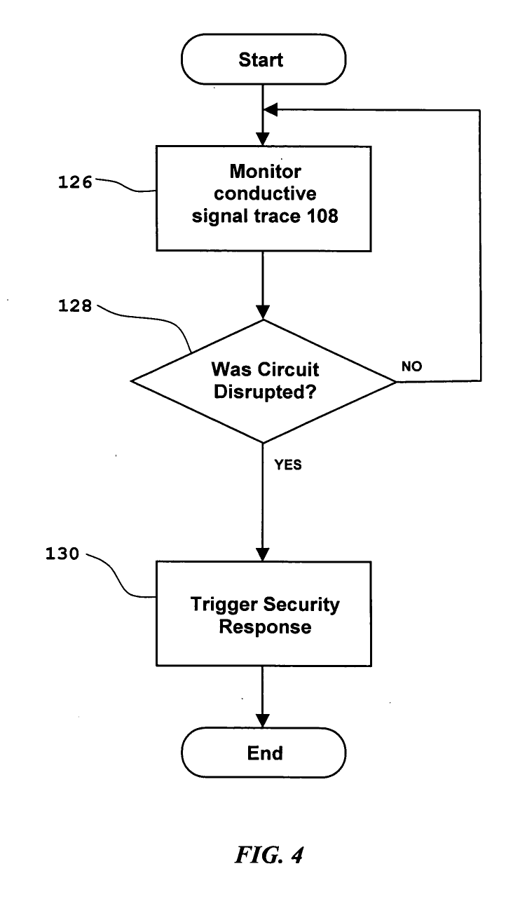

FIG. 4 is a flow diagram of an exemplary operation of tamper detection circuitry 122. Initially, in stage 126, tamper detection circuitry 122 monitors the current in conductive trace 108 of the first substrate 102 and the second substrate 104, e.g. by comparing a detected voltage level to a predetermined level. At stage 128, tamper detection circuitry 122 determines whether one or both of the electrical connections provided by the conductive traces have been interrupted. If the electrical current has been interrupted, the process proceeds to stage 130. If the electrical current has not been interrupted, stages 126 and 128 are repeated. In stage 130, at least one predetermined security response is triggered or provided indicating tampering of the multiplayer printed circuit board 100.

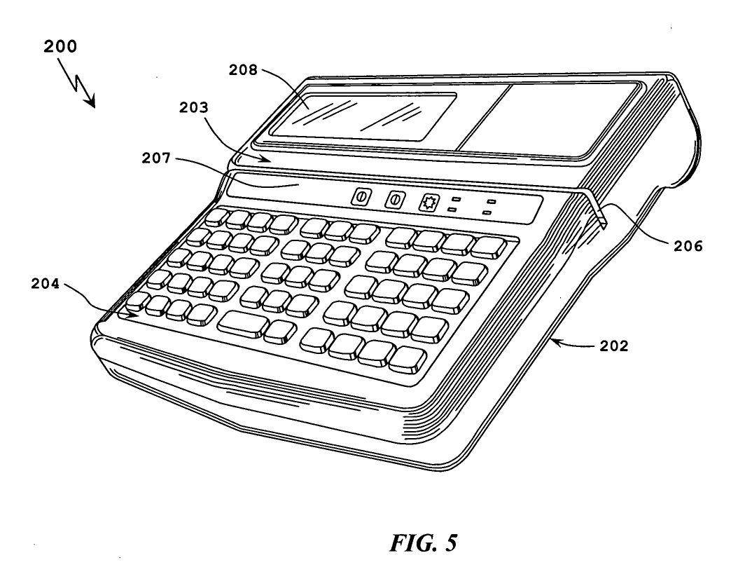

With reference to FIG. 5, a payment terminal 200 is illustrated having there within a multilayer printed circuit board 100 of the present disclosure. The term “payment terminal” as defined herein encompasses any computerized device for performing the normal functions associated with sale transactions, such as, for example, a point-of-sale terminal, used in a variety of industries. One example of a point-of-sale terminal is disclosed in U.S. Pat. No. 5,334,821 to Campo et al., the entire contents of which are hereby incorporated by reference. Payment terminal 200 is adapted for recording and tracking customer orders, process credit and debit cards and connect to other systems in a network. Therefore, information security is necessary to provide for guarding sensitive information, such as, for example, bank account and credit card information, social security numbers, personal identification numbers, etc.

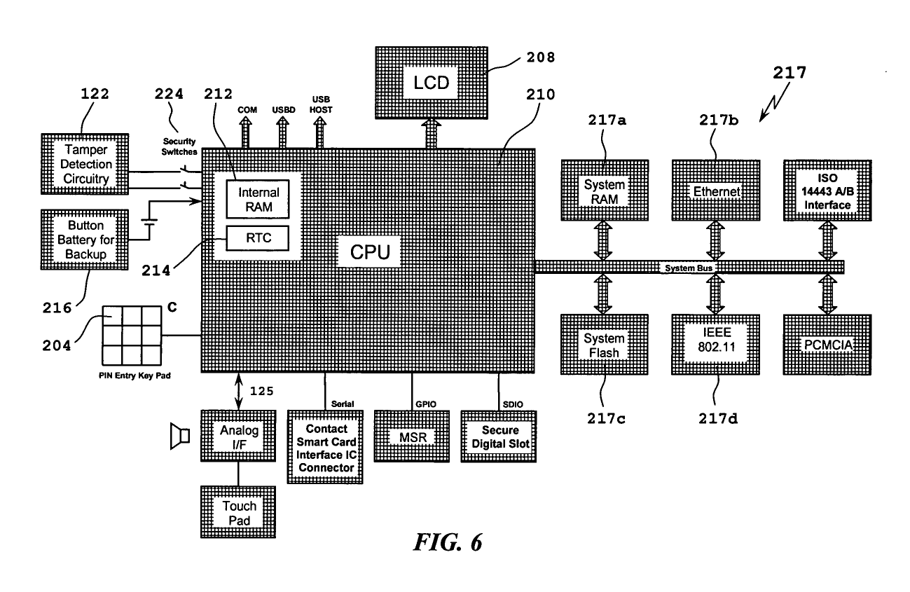

Generally, payment terminal 200 includes a housing 202 having a generally flat front face 203, an input device such as keypad 204, and a display 208, such as, for example, a multi-line Liquid Crystal Display (LCD). A transverse slot 206 and a magnetic card reader 207 for receiving and reading data from a plastic credit card are positioned on flat front surface 203. A central processing unit (CPU) 210 (FIG. 6) is included for executing program specific programs and facilitating input/output data signals for a particular application. It is envisioned that CPU 210 and all electronic components of payment terminal 200 are mounted onto third substrate 106 of multilayer printed circuit board 100. Moreover, first second and third substrates 102, 104 and 106 of multilayer printed circuit board 100 may be supported together with each other as a unitary structure for positioning within housing 202 of payment terminal 200.

With reference to FIG. 6, a block diagram of the integrated circuitry of payment terminal 200 is illustrated. CPU 210 includes inter alia an internal random access memory (RAM) 212 and a real time clock (RTC) 214 for keeping track of the time even when the power supply of payment terminal 200 is unavailable. A back-up battery 216 is included for keeping RAM 212 and RTC 214 active when the main power supply is unavailable. As illustrated by the figure, both keypad 204 and display 208 include circuitry connected to CPU 210. A smart card connector 218 is also provided for storing data, as known in the art. Moreover, a plurality of components 217 is also included for facilitating the operation of payment terminal 200 such as an external system RAM 217a, Ethernet 217b, system flash ROM 217c, a wireless module 217d, etc.

Tamper detection circuitry 122 is provided and is connected to a security switch 224. Tamper detection circuitry 122 is in operable communication with first and second substrates 102 and 104 as discussed in detail hereinabove. In the event of tampering with multilayer printed circuit board 100, security switch 224 will close such that tamper detection circuitry 122 will provide a security response, in a manner described in detail hereinabove.

It will be understood that numerous modifications and changes in form and detail may be made to the embodiments of the present disclosure. It is contemplated that numerous other configuration of the multilayer printed circuit board 100 may be used, and the components of the integrated circuitry may be selected from numerous electronic circuits other than those specifically disclosed. Therefore, the above description should not be construed as limiting the disclosed multilayer printed circuit board but merely as exemplifications of the various embodiments thereof. Those skilled in the art will envision numerous modifications within the scope of the present disclosure as defined by the claims appended hereto.

What is claimed is:

1. A multisubstrate printed circuit board, comprising:
first and second substrate each having a conductive trace;
at least one integrated circuit mounted on a third substrate, the third substrate being positioned between the first and the second substrate; and
tamper detection circuitry in electrical communication with at least one of the conductive traces and configured to provide a security response after detection of an interruption in an electrical connection provided by the at least one conductive trace.

2. The multisubstrate printed circuit board as recited in claim 1, wherein each conductive trace is respectively embedded in the first and second substrates.

3. The multisubstrate printed circuit board as recited in claim 1, wherein the tamper detection circuitry comprises:
a transmitter for transmitting data signals to a remote processor; and
a receiver for receiving data signals from the remote processor.

4. The multisubstrate printed circuit board as recited in claim 1, further comprising a protective casing positioned about the third substrate, the protective casing being interposed between the first and second substrate, wherein the protective casing includes a conductive film in communication with the tamper detection circuitry.

5. The multisubstrate printed circuit board as recited in claim 4, wherein the tamper detection circuitry provides the security response when the integrity of the conductive film has been compromised.

6. The multisubstrate printed circuit board as recited in claim 6, wherein the at least one integrated circuit is mounted within a ball grid array.

7. The multisubstrate printed circuit board as recited in claim 1, wherein the security response is selected from the group consisting of corrupting the information data, destruction of the information data, system shut down, sounding an audio alarm, transmitting a warming message, and a combination thereof.

8. An electrical device comprising:
a housing; and
a multilayer printed circuit board mounted within the housing, the multilayer printed circuit board comprising:
first and second substrates each having a conductive trace;
a third substrate positioned between the first and the second substrates; and
tamper detection circuitry in electrical communication with at least one of the conductive traces and being configured to provide a security response after detection of an interruption in an electrical connection provided by the at least one conductive trace.

9. The electrical device as recited in claim 8, wherein the first and the second substrate are arranged in mutually parallel relationship.

10. The electrical device as recited in claim 8, wherein the housing includes a protective casing positioned about an outer surface of the first and the second substrate, wherein the protective casing includes a conductive film, wherein the tamper detection circuitry triggers a security response when the integrity of the conductive film has been compromised.

11. The electrical device as recited in claim 8, wherein the third substrate includes at least one circuitry package having at least one electrical connector mounted thereupon.

12. The electrical device as recited in claim 11, wherein the at least one circuitry package is mounted within a ball grid array.

13. The electrical device as recited in claim 8, wherein the security response is selected from the group consisting of corrupting the information data, destruction of the information data, system shut down, sounding an audio alarm, transmitting a warming message, and a combination thereof.

14. The electrical device as recited in claim 8, wherein the tamper detection circuitry comprises:
a transmitter for transmitting data signals to a remote processor; and
a receiver for receiving data signals from the remote processor.

15. A method for detecting tampering of a printed circuit board, the method comprising:
mounting at least one integrated circuit onto the printed circuit board;
positioning the printed circuit board between a first and second substrate;
providing a conductive trace on at least one of the first and second substrate; and
providing a security response after detection of an interruption in an electrical connection provided by the conductive trace.

16. The method of securing information according to claim 15, wherein the at least one integrated circuit is mounted within a ball grid array.

17. The method of securing information according to claim 15, wherein the security response is selected from the group consisting of corrupting the information data, destruction of the information data, system shut down, sounding an audio alarm, transmitting a warming message, and a combination thereof.

18. The method of securing information according to claim 15, wherein the plurality of integrated circuits is selected from a group consisting of Random Access Memory, Read Only Memory, Digital Signal Processors, Real Time Clock, and a combination thereof.

19. The of securing information according to claim 15, further comprising the step of interposing a protective case between the first and second substrate, wherein the protective case is positioned about the third substrate.

20. The method of securing information according to claim 18, wherein the protective casing includes a conductive film in communication with the tamper detection circuitry.

21. The method of securing information according to claim 19, wherein, wherein the security response is provided when the integrity of the conductive film has been compromised.

22. A printed circuit board, comprising:
first and second conductive signal traces;
at least one integrated circuit mounted on a substrate; and
tamper detection circuitry in electrical communication with at least one of the first or second conductive traces and configured to provide a security response after detection of an interruption in an electrical connection provided by the at least one first or second conductive trace;
wherein the first and second conductive signal traces are mounted to at least one of the at least one integrated circuit and substrate.
